(19) United States
(12) Patent Application Publication
(10) Pub. No.: US 2023/0188103 A1
(43) Pub. Date: Jun. 15, 2023

(54) DIGITALLY CONTROLLED RF POWER AMPLIFIER

(71) Applicants: SKAIChips Co., Ltd., Suwon-si (KR); Research & Business Foundation SUNGKYUNKWAN UNIVERSITY, Suwon-si (KR)

(72) Inventors: Kang Yoon LEE, Seoul (KR); Reza EFTEKHARI RAD, Suwon-si (KR); Yeon Jae JUNG, Seoul (KR); Jong Wan JO, Suwon-si (KR)

(73) Assignees: SKAIChips Co., Ltd., Suwon-si (KR); Research & Business Foundation SUNGKYUNKWAN UNIVERSITY, Suwon-si (KR)

(21) Appl. No.: 18/078,957

(22) Filed: Dec. 10, 2022

(30) Foreign Application Priority Data
Dec. 13, 2021 (KR) 10-2021-0178068

(51) Int. Cl. H03F 3/24; H03F 3/45; H03G 1/00

(52) U.S. Cl. CPC H03F 3/245; H03F 3/45179; H03G 1/0023; H03G 1/0088; H03F 2200/451

(57) ABSTRACT

A technology related to a power amplifier used in a wireless communication circuit is disclosed. A radio frequency (RF) power amplifier includes a plurality of unit differential amplifiers of which inputs are connected to a common input terminal and outputs are connected to a common adder, and having a gain of a weight of a corresponding bit of a binary gain control word. Each of the differential amplifiers may be configured as a complementary metal-oxide semiconductor (CMOS) differential cascode amplifier. In addition, the RF power amplifier may include a structure in which a plurality of attenuators of the same structure are cascade-connected so that an attenuation rate may be linearly and digitally controlled and an output of each attenuator is connected to an output adder through differential buffers of which turn-on and turn-off are controlled by a controller.

This application claims priority from Korean Patent Application No. 10-2021-0178068, filed Dec. 13, 2021, in the Korean Intellectual Property Office, the disclosure of which is incorporated herein by reference in its entirety.

### BACKGROUND

### 1. Field

The following description relates to a technology related to a power amplifier used in a wireless communication circuit.

### 2. Description of Related Art

Patent No. 10-0,310,405 registered on Sep. 17, 2001 discloses a gain control amplifier having a structure in which a differential amplifier stage having an emitter current, which can be controlled by logic of a binary control signal, is cascaded. Here, an amplification coefficient of a differential amplifier depends on the on-resistance of a metal-oxide semiconductor (MOS) transistor, and this on-resistance is easily affected by a diffusion process during a semiconductor process and is influenced by an operating temperature, and thus causes instability of the amplification coefficient. This prior art proposes a solution by connection of emitters of the differential amplifier to a pair of bipolar transistors in common to secure the linearity of gain control.

However, a circuit including a complementary metal-oxide semiconductor (CMOS) transistor and a bipolar transistor is disadvantageous in terms of circuit arrangement and design compared to a circuit composed of only a CMOS transistor. Further, the amplifier according to the prior art has a structure in which outputs of differential amplifiers are cascade-connected to each other, and thus has a structure which is disadvantageous in terms of stability of output impedance or gain control.

### SUMMARY

The following description relates to providing a radio frequency (RF) power amplifier whose stability of linear gain adjustment is improved.

Further, the following description relates to providing a linear gain adjustment structure suitable for a semiconductor process of an RF power amplifier.

In one general aspect, a radio frequency (RF) power amplifier includes a plurality of unit differential amplifiers of which inputs are connected to a common input terminal and outputs are connected to a common adder, and having a gain of a weight of a corresponding bit of a binary gain control word.

According to an additional aspect, each of the differential amplifiers constituting the RF power amplifier may be configured as a complementary metal-oxide semiconductor (CMOS) differential cascode amplifier.

According to an additional aspect, the RF power amplifier may control a gain value according to a gain setting value, and may sense differential output fluctuation and compare the differential output fluctuation with a reference value for each gain value to adjust the gain value determined in a direction of reducing the output fluctuation.

According to an additional aspect, the RF power amplifier may further include a structure in which a plurality of attenuators of the same structure are cascade-connected so that an attenuation rate may be linearly and digitally controlled and an output of each attenuator is connected to an output adder through differential buffers of which turn-on and turn-off are controlled by a controller.

According to an additional aspect, each of the differential buffers to which the attenuators are connected may be configured as a differential cascode amplifier.

### BRIEF DESCRIPTION OF THE DRAWINGS

FIG. 1 is a block diagram illustrating a configuration of a radio frequency (RF) power amplifier according to one embodiment.

FIG. 2 illustrates a more detailed configuration of the embodiment of FIG. 1.

FIG. 3 is a block diagram illustrating a configuration of an RF power amplifier according to another embodiment.

FIG. 4 illustrates more detailed configurations of a 1/2 attenuator and a differential buffer in the embodiment of FIG. 3.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The above-described and additional aspects are embodied through the embodiments described with reference to the accompanying drawings. It is understood that the components of each embodiment may be variously combined within one embodiment or components of another embodiment unless otherwise mentioned or contradicted by each other. The terms used in the specification and the claims should be interpreted as meanings and concepts consistent with the invention or the proposed technical spirit based on the principle that the inventor may appropriately define the concept of a term to describe the invention thereof in the best way. Hereinafter, preferable embodiments of the present invention will be described in detail with reference to the accompanying drawings.

<Description of Invention of Claim 1>

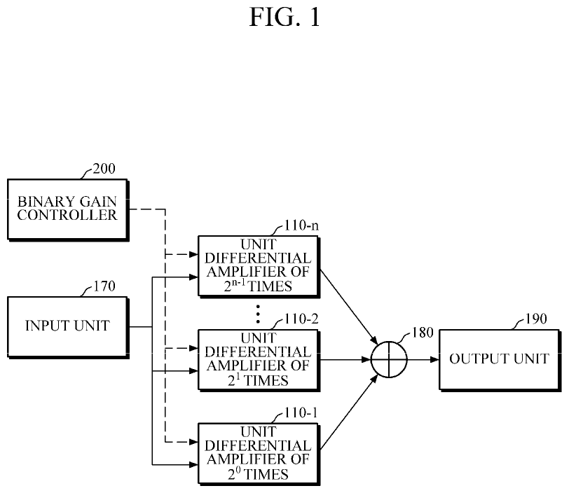

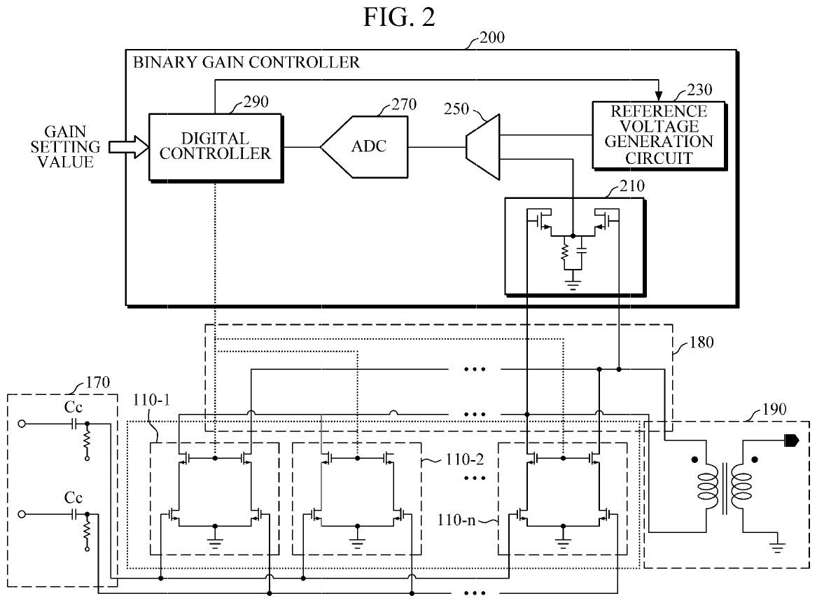

According to one aspect, a radio frequency (RF) power amplifier includes a plurality of unit differential amplifiers of which inputs are connected to a common input terminal and outputs are connected to a common adder, and having a gain of a weight of a corresponding bit of a binary gain control word. FIG. 1 is a block diagram illustrating a configuration of an RF power amplifier according to one embodiment. FIG. 2 illustrates a more detailed configuration of the embodiment of FIG. 1.

As shown in the drawings, the RF power amplifier according to one embodiment includes a plurality of unit differential amplifiers 110-1, 110-2, . . . , and 110-n, a binary gain controller 200, and an adder 180. Inputs of the plurality of unit differential amplifiers 110-1, 110-2, . . . , and 110-n are connected to a common input terminal, and the plurality of unit differential amplifiers 110-1, 110-2, . . . , and 110-n have a gain of a weight of a corresponding bit of a binary gain control word.

According to an additional aspect, each of the plurality of unit differential amplifiers may be configured as a complementary metal-oxide semiconductor (CMOS) differential cascode amplifier. The cascode amplifier is a two-stage amplifier composed of a common-emitter stage and a common-base stage, has high isolation between an input and an output, and has high input/output and bandwidth characteristic. The unit differential amplifier may be turned on/off by switching a voltage applied to each common-base stage.

Four CMOS transistors constituting the cascode amplifier have different sizes according to a multiplied gain value of each unit differential amplifier. Since areas thereof are different, area efficiency may be improved by disposing four CMOS transistors of the same unit differential amplifier adjacent to each other in a shape similar to a quadrangle, and gradationally disposing the CMOS transistors according to the sizes on a layout.

The binary gain controller 200 is connected to the plurality of unit differential amplifiers so that each bit of the binary gain control word to be output turns on or off the corresponding unit differential amplifier. For example, when the binary gain controller outputs a 4-bit binary gain control word, the RF power amplifier includes a total of four unit differential amplifiers, and an amplified gain is adjusted in 2⁴=16 steps. An output of each of the 4 bits of the binary gain control word is connected to a unit differential amplifier to which each bit corresponds.

According to an additional aspect, the RF power amplifier may control a gain value according to a gain setting value, and may sense differential output fluctuation and compare the differential output fluctuation with the reference value for each gain value to adjust the gain value determined in a direction of reducing the output fluctuation. As shown in FIG. 2, in one embodiment, the binary gain controller 200 includes a comparator 250 and a digital controller 290. The digital controller 290 outputs a binary gain control word according to the gain setting value. The gain setting value may be input from the outside or from another circuit component, for example, a circuit which senses an input RF voltage. Meanwhile, the digital controller 290 controls a reference voltage generation circuit 230 so that a reference voltage determined according to the gain setting value is generated.

An output detection circuit 210 detects an output voltage of the adder 180. In the illustrated embodiment, the output detection circuit 210 detects a differential voltage of a differential output. The comparator 250 compares an output voltage output from the output detection circuit 210 with the reference voltage for each gain setting value and outputs a differential value. An analog-to-digital converter 270 converts an output of the comparator 250 to a digital value. The digital controller 290 adjusts the binary gain control word determined according to the gain setting value in a direction of reducing the output fluctuation output from the comparator 250 and outputs the binary gain control word. For example, the digital controller 290 may adjust the binary gain control word at an interval of 0.1 msec.

The adder 180 adds the outputs of the plurality of unit differential amplifiers 110-1, 110-2, . . . , and 110-n, and outputs the added result. In the illustrated embodiment, the adder 180 is implemented as a wired OR circuit. An output unit 190 is implemented as an output transformer in the illustrated embodiment.

<Description of Invention of Claim 4>

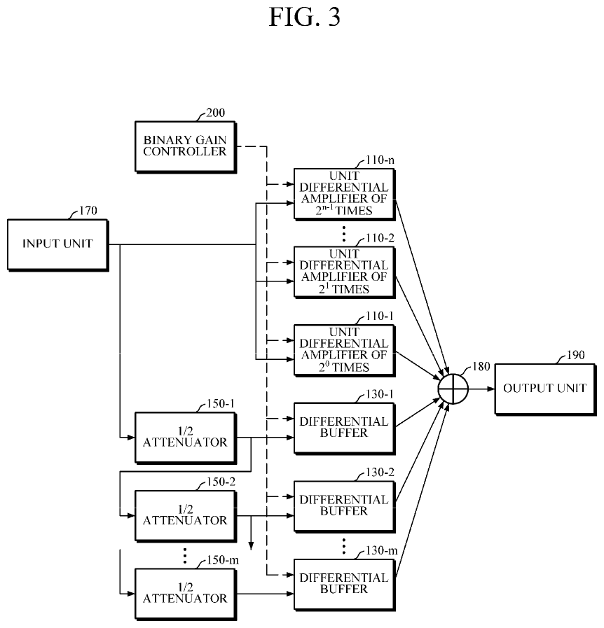

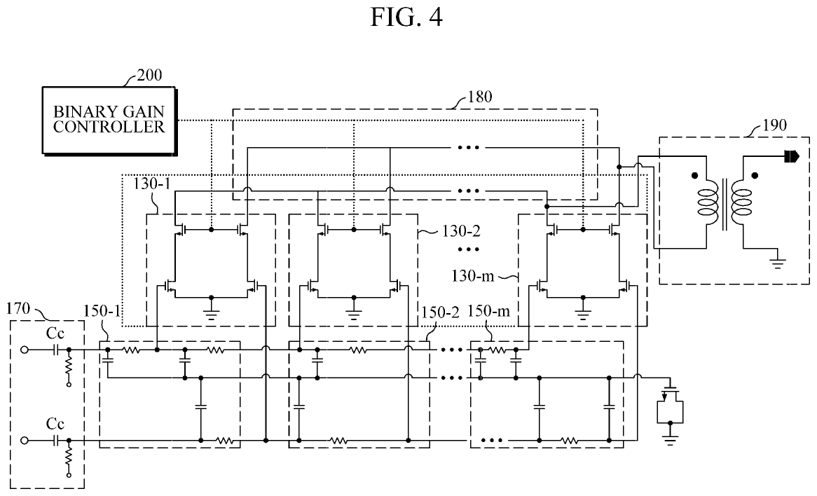

According to an additional aspect, the RF power amplifier may further include a structure in which a plurality of attenuators of the same structure are cascade-connected so that an attenuation rate may be linearly and digitally controlled and an output of each attenuator is connected to an output adder through differential buffers of which turn-on and turn-off are controlled by a controller. FIG. 3 is a block diagram illustrating a configuration of an RF power amplifier according to another embodiment. FIG. 4 illustrates more detailed configurations of a 1/2 attenuator and a differential buffer in the embodiment of FIG. 3.

As shown in the drawings, the RF power amplifier according to another embodiment further includes a plurality of 1/2 attenuators 150-1, 150-2, . . . , and 150-m, and a plurality of differential buffers 130-1, 130-2, . . . , compared to the embodiment shown in FIG. 1 or 2. The plurality of 1/2 attenuators 150-1, 150-2, . . . , and 150-m are cascade-connected to each other from a common input terminal. Input signals are attenuated by 1/2, 1/2², 1/2³, . . . and 1/2^{m} through the 1/2 attenuators. Inputs of the differential buffers 130-1, 130-2, . . . , and 130-m are respectively connected to outputs of the corresponding 1/2 attenuators 150-1, 150-2, . . . , and 150-m, and outputs of the differential buffers 130-1, 130-2, . . . , and 130-m are connected to the adder 180 to be added to outputs of a plurality of unit differential amplifiers 110-1, 110-2, . . . , and 110-n.

According to an additional aspect, each of the plurality of differential buffers 130-1, 130-2, . . . , and 130-m may be configured as a CMOS differential cascode amplifier. The cascode amplifier is a two-stage amplifier composed of a common-emitter stage and a common-base stage, has high isolation between an input and an output, and has high input/output and bandwidth characteristic. The differential amplifier may be turned on/off by switching a voltage applied to each common-base stage.

The binary gain controller 200 is connected to a common base of the differential buffer so that each bit of a binary attenuation control word to be output turns on or off the corresponding differential buffer. For example, when the binary gain controller outputs a 4-bit binary attenuation control word, the RF power amplifier includes a total of four differential buffers, and an attenuated value is adjusted in 2⁴=16 steps. An output of each of the 4 bits of the binary attenuation control word is connected to the common base of the buffer to which each bit corresponds.

In the embodiment shown in FIGS. 3 and 4, the binary gain controller 200 outputs the binary gain control word output from the embodiment shown in FIGS. 1 and 2 and additionally outputs the binary attenuation control word. In the control word output by the binary gain controller 200, it can be seen that the binary gain control word corresponds to an integer unit, and the binary attenuation control word corresponds to a decimal unit. Since an amplification rate is controlled step by step in binary and an attenuation rate is also controlled step by step in binary, the amplification rate of the power amplifier may be linearly controlled in delicate steps.

According to an additional aspect, the RF power amplifier may control an attenuation value according to a gain setting value, and may sense differential output fluctuation and compare the differential output fluctuation with a reference value for each attenuation value to adjust a gain value determined in a direction of reducing the output fluctuation. The binary gain controller 200 shown in FIG. 4 has a structure similar to the binary gain controller 200 shown in FIG. 2 including the comparator 250 and the digital controller 290. The comparator is functionally the same as the comparator shown in FIG. 2 except for a difference that an output voltage output from the adder is sensed and compared with the reference voltage for each attenuation setting value. The digital controller outputs a binary attenuation control word according to the attenuation setting value, but is functionally the same in that it outputs the binary attenuation control word adjusted in a direction of reducing the output fluctuation output from the comparator.

The adder 180 adds the outputs of the plurality of unit differential amplifiers 110-1, 110-2, . . . , and 110-n and outputs the added result. In the illustrated embodiment, the adder 180 is implemented as a wired OR circuit. An output unit 190 is implemented as an output transformer in the illustrated embodiment. The adder 180 may be regarded as an enlarged configuration of the adder in the embodiment shown in FIGS. 1 and 2.

According to the present invention, a gain of a radio frequency (RF) power amplifier is linearly controlled by a binary gain control word, and stability of a control step is secured. Since a transistor area is designed so that each unit differential amplifier has a gain of a weight of a corresponding bit of the binary gain control word, an RF power amplifier digitally controlled by a small number of unit differential amplifiers can be implemented. Further, the RF power amplifier is composed of only complementary metal-oxide semiconductor (CMOS) transistors and thus efficiency in a semiconductor process is improved.

In the above, although the present invention has been described with reference to the accompanying drawings, the present invention is not limited thereto, and should be understood to encompass various modifications which may be clearly derived by those skilled in the art. The claims are intended to encompass these modifications.

What is claimed is:

1. A radio frequency (RF) power amplifier comprising:
a plurality of unit differential amplifiers of which inputs are connected to a common input terminal, and having a gain of a weight of a corresponding bit of a binary gain control word;
a binary gain controller connected to the plurality of unit differential amplifiers so that each bit of the binary gain control word to be output turns on or off the corresponding unit differential amplifier; and
an adder configured to add outputs of the plurality of unit differential amplifiers to output a result,
wherein transistors constituting each unit differential amplifier have an area determined according to a gain value of the unit differential amplifier.

2. The RF power amplifier of claim 1, wherein each of the plurality of unit differential amplifiers is implemented as a complementary metal-oxide semiconductor (CMOS) differential cascode amplifier.

3. The RF power amplifier of claim 2, wherein the binary gain controller includes:
a comparator configured to sense an output voltage output from the adder and compare the output voltage with a reference voltage for each gain setting value; and
a digital controller configured to output a binary gain control word according to the gain setting value, wherein the binary gain control word is adjusted in a direction of reducing output fluctuation output from the comparator.

4. The RF power amplifier of claim 1, further comprising:
a plurality of 1/2 attenuators cascade-connected to each other from the common input terminal; and
a plurality of differential buffers of which inputs are respectively connected to outputs of the corresponding 1/2 attenuators, and of which outputs are connected to the adder,
wherein the binary gain controller is further connected to the plurality of differential buffers so that each bit of a binary attenuation control word to be output turns on or off the corresponding differential buffer.

5. The RF power amplifier of claim 4, wherein each of the plurality of differential buffers is implemented as a CMOS differential cascode amplifier.

6. The RF power amplifier of claim 4, wherein the binary gain controller includes:
a comparator configured to sense an output voltage output from the adder and compare the output voltage with a reference voltage for each attenuation setting value; and
a digital controller configured to output a binary attenuation control word according to the attenuation setting value, wherein the binary attenuation control word is adjusted in a direction of reducing output fluctuation output from the comparator.
